(19) United States
(12) Patent Application Publication
(10) Pub. No.: US 2018/0323573 A1
(43) Pub. Date: Nov. 8, 2018

(54) SEMICONDUCTOR LASER AND METHOD OF PRODUCING A SEMICONDUCTOR LASER AND WAFER

(71) Applicant: OSRAM Opto Semiconductors GmbH, Regensburg (DE)

(72) Inventors: Sven Gerhard, Alteglofsheim (DE); Clemens Vierheilig, Tegernheim (DE); Andreas Loeffler, Neutraubling (DE)

(21) Appl. No.: 15/773,592

(22) PCT Filed: Nov. 4, 2016
(86) PCT No.: PCT/EP2016/076705

§ 371 Date: May 4, 2018

(30) Foreign Application Priority Data
Nov. 6, 2015 (DE) 10 2015 119 146.6

(51) Int. Cl. H01S 5/02; H01S 5/026; H01S 5/042; H01S 5/22; H01S 5/022; H01S 5/024

(52) U.S. Cl. CPC H01S 5/0202; H01S 5/026; H01S 5/02461; H01S 5/22; H01S 5/0224; H01S 5/0425

(57) ABSTRACT

A semiconductor laser includes a semiconductor layer sequence, an active zone, a ridge waveguide as an elevation of a top side of the semiconductor layer sequence, the longitudinal axis of which is oriented along the active zone, a contact metalization, and a current flow layer in direct contact with the contact metalization, wherein the top side of the semiconductor layer sequence includes a section adjoining one of the two facets over the width of the section relative to a longitudinal axis of the ridge waveguide, the section includes a subsection of the top side of the ridge waveguide, the subsection adjoins one of two facets over a width of the ridge waveguide relative to the longitudinal axis of the ridge waveguide, the section is partly delimited by a plurality of current flow layer sections of the current flow layer, and the section is free of the current flow layer.

### TECHNICAL FIELD

This disclosure relates to a semiconductor laser, a method of producing a semiconductor laser and a wafer.

### BACKGROUND

A ridge laser is known from DE 10 2012 106 687 A1. A semiconductor laser comprising a ridge structure widened on one side is also known from WO 2015/055644 A1. It could therefore be helpful to provide an improved semiconductor laser, an improved method of producing a semiconductor laser, and an improved wafer.

### SUMMARY

We provide a semiconductor laser including a semiconductor layer sequence including two opposite facets defining a resonator, and an active zone configured between the two facets, a ridge waveguide configured from the semiconductor layer sequence as an elevation of a top side of the semiconductor layer sequence, the elevation lying above the active zone, and the longitudinal axis of which is oriented along the active zone, a contact metalization applied on a top side of the ridge waveguide facing away from the active zone, and a current flow layer in direct contact with the contact metalization, wherein the top side of the semiconductor layer sequence includes a section adjoining one of the two facets over the width of the section relative to a longitudinal axis of the ridge waveguide, the section includes a subsection of the top side of the ridge waveguide, the subsection extends in a manner adjoining the one of the two facets over a width of the ridge waveguide relative to the longitudinal axis of the ridge waveguide, the section is partly delimited by a plurality of current flow layer sections of the current flow layer, and the section is free of the current flow layer.

We also provide a method of producing a semiconductor laser including providing a semiconductor layer sequence including an active zone, wherein the semiconductor layer sequence includes a ridge waveguide configured from the semiconductor layer sequence as an elevation of a top side of the semiconductor layer sequence, the elevation lying above the active zone, and the longitudinal axis of which is oriented along the active zone, wherein a contact metalization is applied on a top side of the ridge waveguide facing away from the active zone, defining two breaking lines extending transversely with respect to the longitudinal axis of the ridge waveguide and parallel to the top side of the semiconductor layer sequence, applying a current flow layer on the semiconductor layer sequence such that, after the applying, the current flow layer is in direct contact with the contact metalization, wherein the top side of the semiconductor layer sequence includes a section adjoining one of the two breaking lines over the width of the section relative to a longitudinal axis of the ridge waveguide, the section includes at least one subsection of the top side of the ridge waveguide, the subsection extends in a manner adjoining the one of the two breaking lines over a width of the ridge waveguide relative to the longitudinal axis of the ridge waveguide, the section is partly delimited by a plurality of current flow layer sections of the current flow layer, and the section is free of the current flow layer, and breaking the semiconductor layer sequence along the two breaking lines such that two opposite facets defining a resonator are formed along the two breaking lines, wherein the active zone is configured between the two facets.

We further provide a wafer including a semiconductor layer sequence including an active zone, wherein the semiconductor layer sequence includes a ridge waveguide configured from the semiconductor layer sequence as an elevation of a top side of the semiconductor layer sequence, the elevation lying above the active zone, and the longitudinal axis of which is oriented along the active zone, and a contact metalization is applied on a top side of the ridge waveguide facing away from the active zone, two breaking trenches defining two breaking lines extending transversely with respect to the longitudinal axis of the ridge waveguide and parallel to the top side of the semiconductor layer sequence, a current flow layer in direct contact with the contact metalization, wherein the top side of the semiconductor layer sequence includes a section adjoining one of the two breaking lines over the width of the section relative to a longitudinal axis of the ridge waveguide, the section includes at least one subsection of the top side of the ridge waveguide, the subsection extends in a manner adjoining the one of the two breaking lines over a width of the ridge waveguide relative to the longitudinal axis of the ridge waveguide, the section is partly delimited by a plurality of current flow layer sections of the current flow layer, and the section is free of the current flow layer.

### BRIEF DESCRIPTION OF THE DRAWINGS

FIG. 1 shows a frontal sectional view of a first semiconductor laser.

FIG. 2 shows a plan view of the first semiconductor laser from FIG. 1.

FIG. 3 shows a plan view of a second semiconductor laser.

FIG. 4 shows an enlarged excerpt from the plan view of the second semiconductor laser from FIG. 3.

FIG. 5 shows a plan view of a third semiconductor laser.

FIG. 6 shows a plan view of a fourth semiconductor laser.

FIG. 7 shows a plan view of a fifth semiconductor laser.

FIG. 8 shows a plan view of a sixth semiconductor laser.

FIG. 9 shows a plan view of a seventh semiconductor laser.

FIG. 10 shows a plan view of a wafer.

FIG. 11 shows a flow diagram of a method of producing a semiconductor laser.

### LIST OF REFERENCE SIGNS

101 Semiconductor laser
103 Semiconductor layer sequence
105 Active zone
107 Facet
109 Ridge waveguide
111 Top side of the semiconductor layer sequence
113 Top side of the ridge waveguide
115 Sidewall
117 Laser mode
119 Contact metalization
121 Passivation layer
123 Current flow layer
201 Further facet
203 Section
205 Subsection
207 Longitudinal axis
209 Width of the section 203
211 Length of the section 203
213, 215, 217 Current flow layer sections
219 Width of the current flow layer section 215
221 Width of the current flow layer section 213
223 Width of the current flow layer section 217
225 Length of the semiconductor layer sequence
227 Width of the semiconductor layer sequence
301 Second semiconductor laser
303 Region
401 Width of the current flow layer
501 Third semiconductor laser
601 Fourth semiconductor laser
603 Further current flow layer
605 Width of the further current flow layer 603
607 Distance between the further current flow layer 603 and the current flow layer 123
701 Fifth semiconductor laser
801 Sixth semiconductor laser
803 Further current flow layer
805 Distance between the further current flow layer 803 and the further current flow layer 603
807 Width of the further current flow layer 803
901 Seventh semiconductor laser
1001 Wafer
1003 Breaking line
1005 Breaking line
1101 Providing
1103 Defining
1105 Applying
1107 Breaking

### DETAILED DESCRIPTION

Our semiconductor laser may comprise:
a semiconductor layer sequence comprising two opposite facets that define a resonator, and an active zone configured between the two facets,
a ridge waveguide configured from the semiconductor layer sequence as an elevation of a top side of the semiconductor layer sequence, the elevation lying above the active zone, and the longitudinal axis of which is oriented along the active zone,
a contact metalization applied on a top side of the ridge waveguide facing away from the active zone, and
a current flow layer in direct contact with the contact metalization,
wherein the top side of the semiconductor layer sequence comprises a section adjoining one of the two facets over the width of the section relative to a longitudinal axis of the ridge waveguide, the section comprises a subsection of the top side of the ridge waveguide, the subsection extends in a manner adjoining the one of the two facets over a width of the ridge waveguide relative to the longitudinal axis of the ridge waveguide, and
the section is free of the current flow layer.

Our method of producing a semiconductor laser may comprise the following steps:
providing a semiconductor layer sequence comprising an active zone, wherein the semiconductor layer sequence comprises a ridge waveguide configured from the semiconductor layer sequence as an elevation of a top side of the semiconductor layer sequence, the elevation lying above the active zone, and the longitudinal axis of which is oriented along the active zone, wherein a contact metalization is applied on a top side of the ridge waveguide facing away from the active zone,
defining two breaking lines extending transversely with respect to the longitudinal axis of the ridge waveguide and parallel to the top side of the semiconductor layer sequence,
applying a current flow layer on the semiconductor layer sequence such that after the applying, the current flow layer is in direct contact with the contact metalization,
wherein the top side of the semiconductor layer sequence comprises a section adjoining one of the two breaking lines over the width of the section relative to a longitudinal axis of the ridge waveguide, the section comprises at least one subsection of the top side of the ridge waveguide, the subsection extends in a manner adjoining the one of the two breaking lines over a width of the ridge waveguide relative to the longitudinal axis of the ridge waveguide, the section is free of the current flow layer, and
breaking the semiconductor layer sequence along the two breaking lines such that two opposite facets that define a resonator are formed along the two breaking lines, wherein the active zone is configured between the two facets.

Our wafer may comprise:
a semiconductor layer sequence comprising an active zone, wherein the semiconductor layer sequence comprises a ridge waveguide configured from the semiconductor layer sequence as an elevation of a top side of the semiconductor layer sequence, the elevation lying above the active zone, and the longitudinal axis of which is oriented along the active zone, wherein a contact metalization is applied on a top side of the ridge waveguide facing away from the active zone,
two breaking trenches defining two breaking lines that extend transversely with respect to the longitudinal axis of the ridge waveguide and parallel to the top side of the semiconductor layer sequence,
a current flow layer in direct contact with the contact metalization,
wherein the top side of the semiconductor layer sequence comprises a section adjoining one of the two breaking lines over the width of the section relative to a longitudinal axis of the ridge waveguide, the section comprises at least one subsection of the top side of the ridge waveguide, the subsection extends in a manner adjoining the one of the two breaking lines over a width of the ridge waveguide relative to the longitudinal axis of the ridge waveguide, and the section is free of the current flow layer.

Our semiconductor lasers comprise in particular and inter alia the concept of providing on the top side of the ridge waveguide one region (or two regions) that directly adjoins one of the two breaking lines (or which respectively adjoin one of the two breaking lines) and is (or are) free of the current flow layer. In other words, no current flow layer is situated in this region, the subsection. This advantageously brings about an improved breaking behavior along the breaking line. This affords the technical advantage, in particular, that an improved breaking quality may be achieved. In particular, a situation in which possible material residues of the current flow layer are located in the active region of the facet after the breaking process may advantageously be avoided. This is the case in particular since a local stress in the region of the breaking lines, along which the facets have formed after the breaking process, is positively influenced for the cleaving or breaking.

This may advantageously afford the technical advantage that the facets comprise a surface that is as smooth as possible, in particular an atomically smooth surface, without comprising defects in the process such as crystal dislocations, for example. A good threshold current may advantageously be achieved as a result. In particular, low operating currents, high efficiencies and a long lifetime may be achieved.

By leaving free a region that directly adjoins one of the two breaking lines on the top side of the ridge waveguide, global and/or respectively local stress fields may be efficiently controlled such that facets comprising a sufficient surface quality may be obtained.

In particular, it is thereby possible to prevent the ridge waveguide region from being overlaid at the location at which the break for producing the facets extends.

The fact that the current flow layer is in direct contact with the contact metalization means, in particular, that no further layer is situated between the current flow layer and the contact metalization. Consequently, the current flow layer touches the contact metallization, for example, directly, that is to say immediately. In particular, there is situated between the contact metalization and the current flow layer no thermally conductive further layer that may be provided, for example, to dissipate heat generated during operation of the semiconductor laser.

That section of the top side of the semiconductor layer sequence which is free of the current flow layer may be provided with the contact metalization. In other words, in particular, the contact metalization is applied or formed on the section, wherein the contact metalization within the section is free of the current flow layer.

The contact metalization may comprise a region free of the current flow layer. The region corresponds to the above-designated section of the top side of the semiconductor layer sequence and/or respectively comprises the above-designated section of the top side of the semiconductor layer sequence.

A ridge waveguide may also be designated as a ridge. A ridge waveguide advantageously brings about an efficient guidance of radiation in a direction parallel to a main extension direction of the semiconductor layer sequence. The guidance of radiation in a direction perpendicular to the main extension direction, parallel to a growth direction of the semiconductor layer sequence, is carried out in particular through layers of the semiconductor layer sequence at least in part not comprised by the ridge. In this context, therefore, the term waveguide relates to a wave guiding in a direction parallel to the main extension direction.

The ridge waveguide is shaped or configured from the semiconductor layer sequence. The waveguide is thus configured as an elevation above remaining regions of the semiconductor layer sequence, in a direction parallel to a growth direction of the semiconductor layer sequence. In other words, the waveguide (ridge waveguide) is configured or formed from a material of the semiconductor layer sequence. A material of the semiconductor layer sequence is removed on both sides of the ridge waveguide. The ridge waveguide extends along an emission direction and/or a resonator longitudinal direction of the semiconductor laser. Besides the synonymous term ridge and/or respectively waveguide, such a ridge waveguide may also be referred to in German as “Ridgewaveguide” or simply just as “Ridge.”

The semiconductor laser may be configured as a ridge laser.

A resonator longitudinal direction is defined, for example, by the facets acting as resonator mirrors and is oriented, for example, perpendicularly to the facets.

The semiconductor laser may comprise a contact metalization. The contact metalization is situated on a top side of the waveguide facing away from the active zone. In particular, the contact metalization touches a semiconductor material of the semiconductor layer sequence that shapes the top side. The contact metalization is preferably formed or shaped from a metal or from a metal alloy. Alternatively or additionally, provision is made for the contact metalization to be formed from and/or respectively to comprise a semiconductor material comprising metallic properties or substantially metallic properties by way of a corresponding doping.

The contact metalization may be formed from one or from a plurality of the materials mentioned below, or comprises one or a plurality of such materials: Pd, Ti, Pt, Ni, ZnO:Al, ZnO:Al, ZnO:Ga, ITO, Rh (rhodium). The work function of the oxidic materials presented is set by way of a corresponding doping, for example.

The semiconductor laser may comprise a current flow layer. The current flow layer is in direct contact with the contact metalization. The current flow layer is designed or configured to electrically connect the contact metalization. By way of example, the current flow layer is configured as a conductor track structure. The current flow layer is configured as a bond pad, for example. The current flow layer may be configured as a bond pad metalization, for example. The current flow layer extends, for example, at least partly over the top side of the waveguide as seen in plan view.

The current flow layer may comprise one of the following materials or consists of one or a plurality of the following materials: Au, Ni, Ti, ZnO:Al, ZnO:Ga, ITO, Pt. Preferably, the current flow layer is formed from Au or from Ti or from Ti—Pt—Au. For example, the current flow layer may be configured or shaped from a plurality of individual layers comprising different materials. In this case, for example, layers of the current flow layer not in direct contact with the top side of the semiconductor layer sequence and/or respectively of the ridge waveguide may be formed from materials other than those mentioned.

Since the ridge waveguide is configured as an elevation of a top side of the semiconductor layer sequence, the top side of the ridge waveguide is also part of the top side of the semiconductor layer sequence. Consequently, in particular the wording “top side of the semiconductor layer sequence” may encompass the top side of the ridge waveguide.

In particular, current is impressed into the semiconductor layer sequence via the contact metalization. No or no significant current is impressed into the semiconductor layer sequence via the current flow layer, in particular at current intensities near a threshold current for the generation of laser radiation. That is to say that the current flow layer substantially electrically contacts the semiconductor laser.

The semiconductor layer sequence is based in particular on a III-V compound semiconductor material. The semiconductor material is, for example, a nitride compound semiconductor material such as AlₙIn₁₋ₙ₋ₘGaₘN, or else a phosphide compound semiconductor material such as AlₙIn₁₋ₙ₋ₘGaₘP, or an arsenide compound semiconductor material such as AlₙIn₁₋ₙ₋ₘ GaₘAs, wherein in each case 0≤n≤1, 0≤m≤1 and n+m≤1. In this case, for example, the semiconductor layer sequence comprises dopants and, for example, additional constituents.

The semiconductor layer sequence comprises, for example, one or a plurality of active zones. An active zone comprises, for example, a single quantum well structure or, for example, a multiple quantum well structure. During use of the semiconductor laser as intended, an electromagnetic radiation is generated in the active zone, for example, in the spectral range of 300 nm to 1500 nm, for example, 380 nm to 600 nm. The generated radiation is a coherent laser radiation during use of the semiconductor laser as intended.

The semiconductor laser may be configured as an edge emitting semiconductor laser.

The semiconductor laser may be produced by our method of producing a semiconductor laser.

The semiconductor laser may be used to produce the wafer.

“Breaking” may mean cleaving, in particular.

The wording “and/or respectively” encompasses in particular the wording “and/or.”

Technical functionalities of the method of producing a semiconductor laser and/or respectively the wafer arise analogously from corresponding technical functionalities of the semiconductor laser, and vice versa.

The width of the section relative to the longitudinal axis of the ridge waveguide may be 30 μm to 80 μm, in particular 35 μm to 55 μm.

A length of the section relative to the longitudinal axis of the ridge waveguide may be 5 μm to 50 μm, in particular 10 μm to 20 μm.

The section may be partly delimited by one or a plurality of current flow layer sections of the current flow layer.

Relative to the longitudinal axis of the ridge waveguide, a respective width of the one or the plurality of current flow layer sections may be 30 μm to 100 μm, in particular 35 μm to 85 μm, preferably 5 μm to 10 μm.

At least one further current flow layer spaced apart from the current flow layer may be applied on the top side of the semiconductor layer sequence.

A respective width of the at least one further current flow layer relative to the longitudinal axis of the ridge waveguide may be 10 μm to 40 μm, in particular 20 μm to 30 μm.

At least one further current flow layer spaced apart from the current flow layer may be applied on the top side of the semiconductor layer sequence.

A respective width of the at least one further current flow layer relative to the longitudinal axis of the ridge waveguide may be 10 μm to 40 μm, in particular 20 μm to 30 μm.

A plurality of further current flow layers may be provided.

Explanations given in association with one further current flow layer are analogously applicable to examples comprising a plurality of further current flow layers, and vice versa. For example, a further current flow layer is not applied on the ridge waveguide. That is to say that according to one example, the further current flow layer is applied on a region of the top side of the semiconductor layer sequence different from the top side of the ridge waveguide.

A facet may also be designated as a laser facet.

The terms length and width relate relative to the longitudinal axis of the ridge waveguide. The width thus denotes a direction transversely with respect to the longitudinal axis. The length thus extends along, that is to say parallel to, the longitudinal axis. The longitudinal axis of the ridge waveguide is that axis of the ridge waveguide extending along the largest extent of the ridge waveguide. The longitudinal axis extends, for example, perpendicularly to the two facets.

Explanations in association with the one of the two facets are analogously applicable to the other of the two facets. Consequently, in particular a corresponding section comprising a corresponding subsection is provided, wherein the corresponding subsection is free of the current flow layer. The same applies to the breaking lines.

A course and/or respectively a contour of the passivation layer and/or respectively of the contact metalization may correspond partly or completely to a contour of the current flow layer.

The passivation layer and/or respectively the contact metalization may extend as far as the facet and/or respectively facets, that is to say to immediately or directly adjoin the latter.

A course and/or respectively a contour of the passivation layer and/or respectively of the contact metalization may be different from a contour of the current flow layer.

The above-described properties, features and advantages and the way in which they are achieved will become clearer and more clearly understood in association with the following description of examples explained in greater detail in association with the drawings.

Hereinafter, identical reference signs may be used for identical features.

Furthermore, for the sake of clarity, it may be provided that not all of the figures depict all of the elements and depict the reference signs for all of the elements.

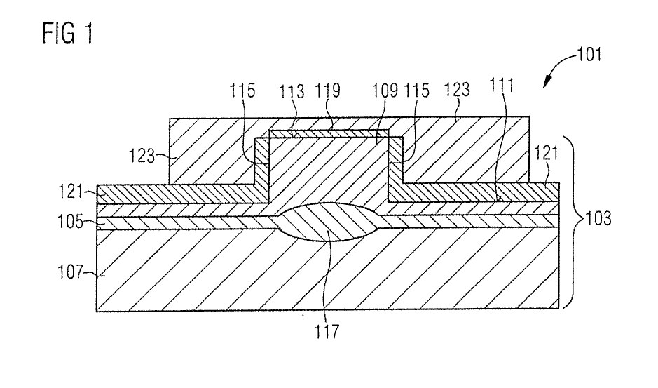

FIG. 1 shows a frontal sectional view of a first semiconductor laser 101.

FIG. 1 shows a view of a facet 107 of the semiconductor laser 101. In general, facets may also be designated as laser facets. The semiconductor laser 101 comprises a semiconductor layer sequence 103. The semiconductor layer sequence 103 comprises an active zone 105. The active zone 105 is configured to generate electromagnetic radiation.

A ridge waveguide 109 in the form of an elevation is configured from the semiconductor layer sequence 103. The ridge waveguide 109 is configured or shaped from the semiconductor layer sequence 103 as an elevation of a top side 111 of the semiconductor layer sequence 103, the elevation lying above the active zone 105. The longitudinal axis (not shown in FIG. 1) of the ridge waveguide 109 is oriented along the active zone 105.

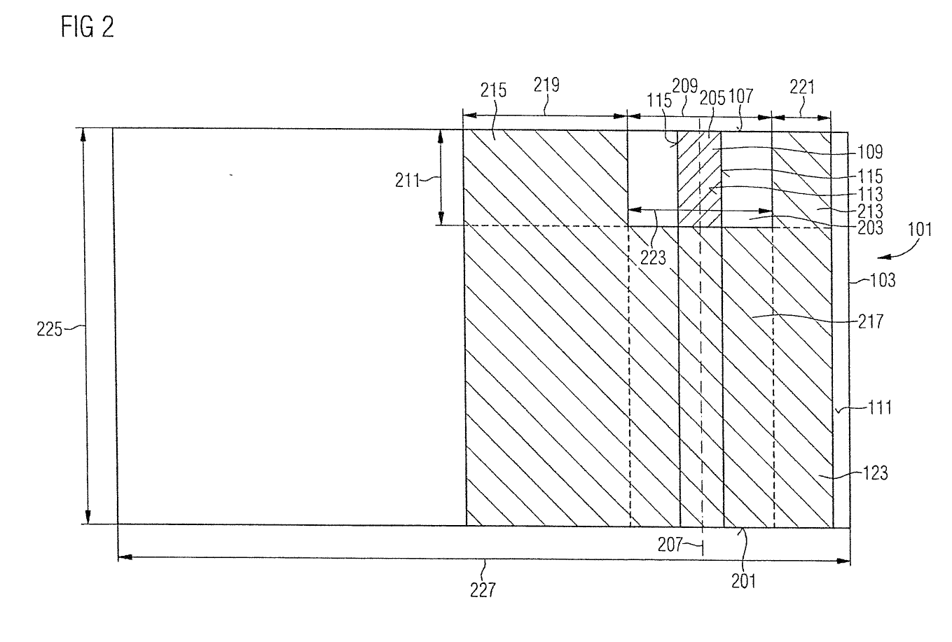

A further facet is provided opposite the facet 107, which further facet is not shown in FIG. 1, but rather in the plan views in the still further FIGS. 2 to 10.

The two facets define a resonator, wherein the active zone 105 lies between the two facets. The two facets form on account of a process of breaking the semiconductor layer sequence 103 along breaking lines in the context of a method of producing a semiconductor laser.

The ridge waveguide 109 comprises a top side 113 facing away from the active zone 105. Since the ridge waveguide 109 is shaped from the top side 111 of the semiconductor layer sequence 103, the top side 113 of the ridge waveguide 109 is thus also part of the top side 111 of the semiconductor layer sequence 103.

The ridge waveguide 109 comprises a top side 113 oriented parallel to the active zone 105. Lateral boundary faces of the ridge waveguide 109 are formed by sidewalls 115. The sidewalls 115 are oriented perpendicularly to the active zone 105. Perpendicularly to the plane of the drawing, the ridge waveguide 109 comprises a main extension direction corresponding to its longitudinal axis. The resonator of the semiconductor laser 101, the resonator being defined by the two facets, is likewise oriented perpendicularly to the plane of the drawing. During operation as intended, the semiconductor laser 101 emits laser radiation within the semiconductor layer sequence 103 perpendicularly to the plane of the drawing. A laser mode that forms during operation as intended is illustrated in the drawing as a thickening of the active zone 105 below the ridge waveguide 109 and is provided with the reference sign 117.

The regions of the semiconductor layer sequence 103 alongside the ridge waveguide 109 and also the sidewalls 115 are covered by a passivation layer 121. The passivation layer 121 is, for example, an electrically nonconductive layer comprising an insulator or, for example, comprising a semiconductor material comprising, for example, a band gap of, for example, at least 4 eV.

By way of example, the passivation layer 121 is formed from one of the materials mentioned subsequently: SiN, SiO, ZrO, TaO, AlO, ZnO. A thickness of the passivation layer 121 is, for example, 100 nm to 2 μm.

A contact metalization 119 is applied on the top side 113 of the ridge waveguide 109. An electric current is impressed into the semiconductor layer sequence 103 via the contact metalization 119.

The contact metalization 119 comprises, for example, one or more of the following materials: Pd, Pt, ZnO, ITO, Ni, Rh. A thickness of the contact metalization 119 is, for example, 20 nm to 500 nm, in particular 30 nm to 300 nm.

The semiconductor laser 101 furthermore comprises a current flow layer 123 in direct contact with the contact metalization 119. The contact metalization 119 may electrically connect via the current flow layer 123. The current flow layer 123 is thus formed from an electrically conductive material. No or no significant electric current is impressed into the semiconductor layer sequence 103 via the current flow layer 123, in particular at current intensities near a threshold current for the generation of laser radiation.

By way of example, a material comprising a good thermal conductivity is used as material for the current flow layer 123 such that the direct contact with the semiconductor layer sequence 103 brings about an improved heat dissipation. For such an improved heat dissipation, for example, parts of the sidewalls 115 likewise can be covered with the current flow layer 123.

The current flow layer 123 likewise covers regions of the passivation layer 121 and is thus applied on the top side 111 of the semiconductor layer sequence 103.

The current flow layer 123 may also be designated as a bond pad metalization, insofar as it brings about an electrical contacting of the contact metalization 119 analogously to a bond pad. The current flow layer 123, for example, is formed from one or a plurality of the following materials and/or respectively comprises one or a plurality of the following materials: Pd, Pt, Ti, Au, ITO, ZnO, Ni, ZnO:Al, ZnO:Ga.

A carrier for the semiconductor layer sequence 103 is not depicted in any of the figures to simplify illustration. However, such a carrier is provided according to one example. Such a carrier is, for example, a growth substrate for the semiconductor layer sequence 103 or a replacement substrate different therefrom.

By way of example, the semiconductor layer sequence 103 is arranged on a wafer.

To achieve a good threshold current, low operating currents, high efficiencies and a long lifetime, the facets of semiconductor lasers must comprise an atomically smooth surface without defects as a result of crystal dislocations. To produce the facets, generally the wafers on which the semiconductor layer sequence is applied are first broken to form individual bars and then singulated to form the individual semiconductor lasers, which may be configured, for example, as a semiconductor laser chip. The bars here define the laser resonator, which is delimited by the facets.

To be able to break the facets with a sufficient surface quality, an accurate control of the global and also local stress fields is necessary. Even small changes in the surface structure of the semiconductor (changes in the dimensions of the ridge waveguide, for example) or the coatings, here in particular the current flow layer, which is configured, for example, as a p-type metalization, may adversely influence the quality of the facets. In laborious experiments, we surprisingly found that in particular, the example of the current flow layer, configured, for example, as a p-type metalization, and of the bond pad has a great influence on the quality of the facets.

However, the shape of the current flow layer, for example, of the bond pad metallization has an influence on the facet quality not only via the locally generated stress fields. In this regard, we likewise found that, on account of the ductility of metal in contrast to the brittly breaking semiconductor, an overlaying of the ridge region at the location at which the break of producing the facets extends may be disadvantageous for the facet quality.

In addition, thick metal at these locations may lead to disadvantages during the process of separating the bars out and may contaminate the facet region by metal residues. Therefore, it is generally advantageous for the facet region of the ridge, that is to say of the ridge waveguide, not to be overlaid with metal.

However, a wide metallized region has advantages when dissipating heat from the semiconductor laser, in particular when mounting the semiconductor laser onto a carrier, wherein here the current flow layer faces the carrier (so-called p-side-down mounting). This is the case in particular since metal readily conducts a heat loss that arises, and contributes to spreading the heat in the direction of a heat sink.

Previously known structures of a bond pad metalization are generally controlled exclusively in respect of the electrical and optical properties of these metal layers, without controlling the influence of these layers on stress fields at the facet and the thermal budget of the semiconductor laser.

Our semiconductors lasers are based on the insight that by providing a suitable p-type metalization (generally by providing a suitable current flow layer) that positively influences the stresses at the mirror facets of the laser resonator and comprise as much metal as possible in the ridge region for dissipating heat from the chips and which in this case positively influences the breaking quality of the laser facts, a semiconductor laser comprising a good threshold current, low operating currents, high efficiencies and a long lifetime may be produced. We provide for a structure of the current flow layer, for example, of the p-type metallization in the region of the ridge and alongside the latter to be structured in an advantageous manner such that the local stress in the region of the facets is positively influenced for cleaving the facets. By leaving free the facet region of the ridge, a good breaking quality is achieved and possible metal residues in the active region of the facet are prevented.

This is implemented in concrete terms by virtue of the fact that the top side 111 of the semiconductor layer sequence 103 comprises a section adjoining one of the two facets over its width, that is to say the width of the section, relative to a longitudinal axis of the ridge waveguide 109, wherein the section comprises a subsection of the top side 113 of the ridge waveguide 109, wherein the subsection extends in a manner adjoining the one of the two facets over a width of the ridge waveguide 109 relative to the longitudinal axis of the ridge waveguide 109 and the section is free of the current flow layer.

That is to say, a region adjoining one of the two facets is provided on the top side 113 of the ridge waveguide 109, wherein the region is free of the current flow layer, i.e., no current flow layer is applied in the region. The ridge region is thus advantageously left free with the current flow layer. The current flow layer is correspondingly structured to configure such a region free of the current flow layer.

The technical advantages and effects are as follows, for example:
During the process of cleaving the semiconductor layer sequence to produce the mirror facets (laser facets) along the breaking lines, the local stress at the mirror facets is influenced in this way to the effect that the break ideally passes through the material of the semiconductor layer sequence and an atomically smooth facet region arises. This leads to better electro-optical properties of the semiconductor laser such as, for example, a lower threshold and a lower operating current and also a higher yield.
As a result of the controlled stress budget, better adhesion of the dielectric mirror layers generally applied on the facets is achieved during laser operation, which leads to a longer lifetime of the semiconductor laser.
As a result of applying the current flow layer alongside the ridge while at the same time leaving free the facet region, dissipation of heat from the semiconductor laser is ensured, particularly in p-side-down mounting.

The figures described below show how the section comprising the subsection may be configured in specific detail. In this case, for the sake of clarity, provision is made for the contact metalization 119 and the passivation layer 121 not to be depicted.

The explanations given above and/or respectively below, which explanations were given in association with the contact metalization 119 and the passivation layer 121 with reference to FIG. 1, also apply in respect of the further figures and, in accordance with preferred examples, also apply independently of the examples explained and shown in the figures. The corresponding features are also disclosed in a manner detached from the examples specifically described and shown in the figures.

A course and/or respectively a contour of the passivation layer 121 and/or respectively of the contact metalization 119 may correspond partly or completely to a contour of the current flow layer 123.

The passivation layer 121 and/or respectively the contact metalization 119 may extend as far as the facet 107, that is to say to immediately or directly adjoin the latter.

A course and/or respectively a contour of the passivation layer 121 and/or respectively of the contact metalization may be different from a contour of the current flow layer 123.

FIG. 2 shows a plan view of the first semiconductor laser 101 from FIG. 1. In this case, the plan view relates to the view from above of the top side 111 of the semiconductor layer sequence 103.

The further facet situated opposite the facet 107 is now discernible on account of the plan view. The further facet is provided with the reference sign 201.

The section free of the current flow layer 123 is identified by the reference sign 203. The section 203 adjoins the facet 107. The section 203 comprises a quadrilateral shape, wherein one side of the quadrilateral is delimited by the facet 107. The other three sides of the quadrilateral are delimited by current flow layer sections 213, 215, 217 of the current flow layer 123. In other words, the current flow layer 123 is applied on the top side 111 of the semiconductor layer sequence 103 such that a quadrilateral region, the section 203, of the top side 111 of the semiconductor layer sequence 103 is left free in this case. A width of the section 203 is identified by a double-headed arrow with the reference sign 209.

The width 209 is, for example, 30 μm to 80 μm, in particular 35 μm to 55 μm.

A length of the section 203 is identified by a double-headed arrow with the reference sign 211. The length 211 is, for example, 5 μm to 50 μm, in particular 10 μm to 20 μm.

The terms length and width make reference relative to the longitudinal axis 207 of the ridge waveguide 109. The width thus denotes a direction transversely with respect to the longitudinal axis 207. The length thus extends along, that is to say parallel to, the longitudinal axis 207. The longitudinal axis 207 of the ridge waveguide 109 is that axis of the ridge waveguide 109 which extends along the largest extent of the ridge waveguide. The longitudinal axis 207 thus extends perpendicularly to the two facets 107, 201.

A width of the current flow layer section 215 is identified by a double-headed arrow with the reference sign 219. The width 219 is, for example, 30 μm to 100 μm, in particular 35 μm to 85 μm.

A width of the current flow layer section 213 is identified by a double-headed arrow with the reference sign 221. The width 221 is, for example, 5 μm to 10 μm.

A width of the current flow layer section 217 is identified by a double-headed arrow with the reference sign 223. On account of the quadrilateral shape of the section 203, the width 223 corresponds to the width 209 of the section 203.

The section 203 furthermore comprises a subsection 205 defined on the top side 113 of the ridge waveguide 109. The subsection 205 likewise adjoins the facet 107 over the width of the ridge waveguide 109. The subsection 205 extends in a manner adjoining the facet 107 over the width, that is to say over the entire width, of the ridge waveguide 109.

Consequently, relative to the plan view, a region of the top side 111 of the semiconductor layer sequence 103 is thus free of the current flow layer 123, wherein the region (section 203) comprises a section of that edge of the top side 111 of the semiconductor layer sequence 103 which is formed by the facet 107.

A length of the semiconductor layer sequence 103 is identified by a double-headed arrow with the reference sign 225. The length 225 is, for example, 600 μm to 2000 μm.

A width of the semiconductor layer sequence 103 is identified by a double-headed arrow with the reference sign 227. The width 227 is, for example, 100 μm to 400 μm.

A width of the current flow layer 123 is thus the sum of the widths 219, 223 and 221. A length of the current flow layer 123 corresponds to the length 225 insofar as the current flow layer 123 extends in a longitudinal direction, that is to say longitudinally with respect to the longitudinal axis 207 from the facet 107 to the further facet 201.

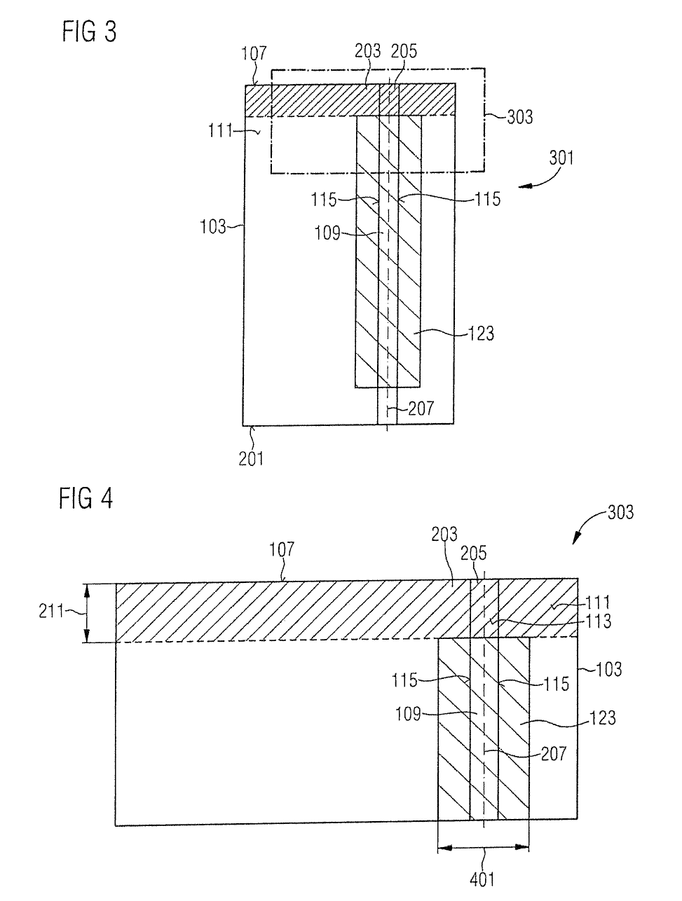

FIG. 3 shows a second semiconductor laser 301 in a plan view of the top side 111 of the semiconductor layer sequence 103.

In this example, the current flow layer 123 does not extend from the facet 107 to the further facet 201, but rather is each applied in a manner spaced apart from the facets 107, 201 on the top side 111 of the semiconductor layer sequence and thus also on the top side 113 of the ridge waveguide 109. The current flow layer 123 comprises a rectangular shape in the plan view.

On account of the current flow layer 123 being arranged in a manner spaced apart from the two facets 107, 201, a section 203 is thus configured which adjoins the facet 107 and comprises a subsection 205 formed on the top side 113 of the ridge waveguide 109, wherein the section 203 is free of the current flow layer 123.

The section 203 is illustrated in a hatched manner in FIG. 3.

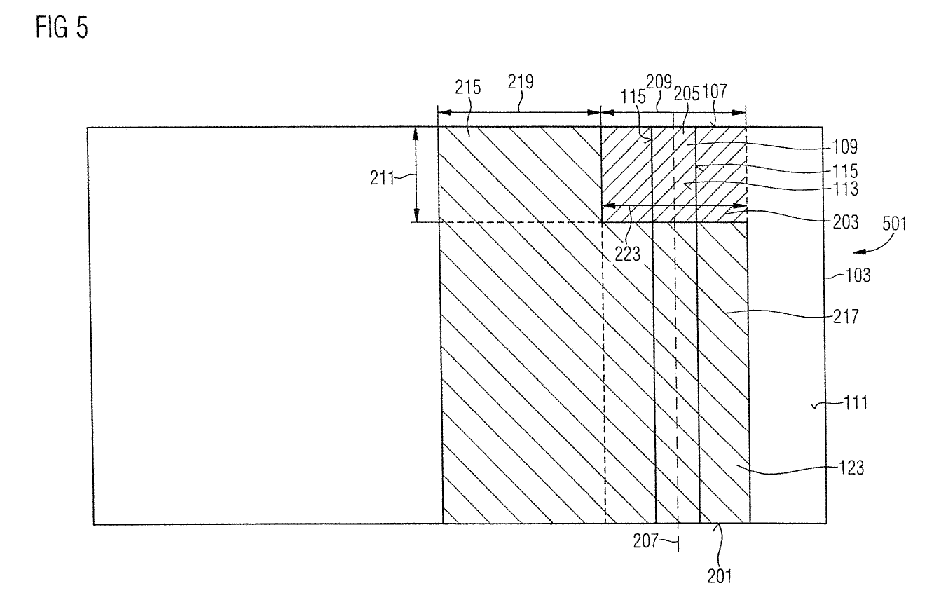

The reference sign 303 points to a quadrilateral enclosing a region of the semiconductor laser 301, which region is illustrated in an enlarged view in FIG. 4.

As is shown in FIG. 4, the current flow layer 123 is arranged at a distance 211 from the facet 107, which distance corresponds to the length of the section 203.

Although not explicitly shown in FIGS. 3 and 4, thus also applying to FIG. 1 and the further figures, in further examples (not shown) a corresponding section free of the current flow layer 123 is also configured at the facet 201. In other words, the explanations given in association with the section 203 adjoining the facet 107 analogously apply to the further facet 201.

FIG. 4 depicts a double-headed arrow with the reference sign 401 that identifies the width of the current flow layer 123.

FIG. 5 shows a third semiconductor laser 501 in a plan view of the top side 111 of the semiconductor layer sequence 103.

The semiconductor laser 501 is substantially configured analogously to the semiconductor laser 101 of FIG. 2. As a difference, the current flow layer section 213 is lacking, with the result that the section 203 that is free of the current flow layer 123 is open toward one side. That is to say that at one side the section 203 is no longer delimited by a current flow layer section.

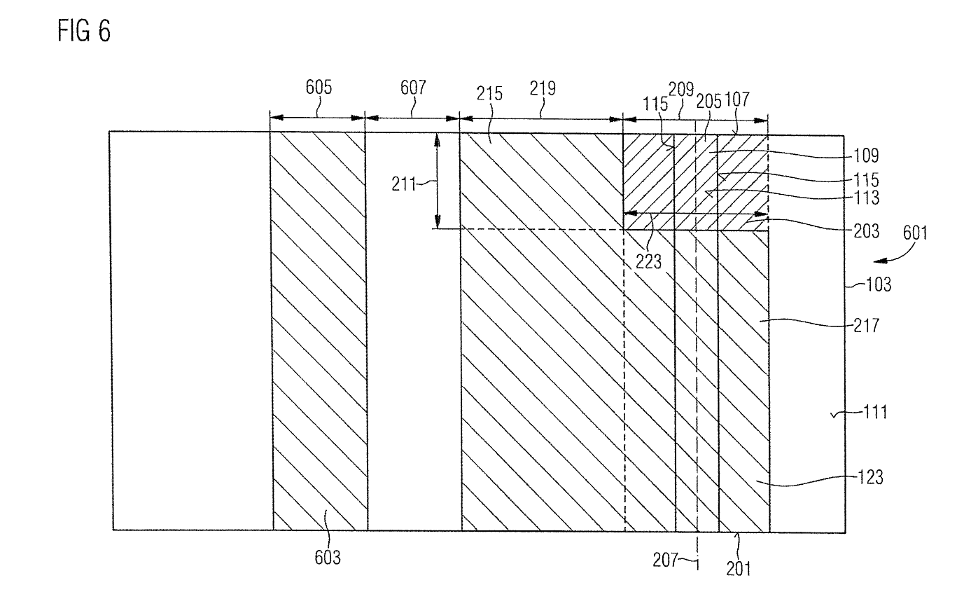

FIG. 6 shows a fourth semiconductor laser 601 in a plan view of the top side 111 of the semiconductor layer sequence 103.

The current flow layer 123 is substantially configured analogously to the current flow layer 123 in accordance with the semiconductor laser 501 from FIG. 5, wherein a width of the current flow layer 123 is decreased or reduced in comparison with the semiconductor laser 501.

As a further difference, a further current flow layer 603 is provided, which extends in a strip-shaped fashion from the facet 107 to the facet 201. The further current flow layer 603 is applied in a manner spaced apart from the current flow layer 123. This distance is identified by a double-headed arrow with the reference sign 607. The distance 607 is, for example, 10 μm to 40 μm, in particular 20 μm to 30 μm.

A width of the further current flow layer 603 is identified by a double-headed arrow with the reference sign 605. The width 605 is, for example, 10 μm to 40 μm, in particular 20 μm to 30 μm.

Providing the further current flow layer 603 spaced apart from the current flow layer 123 affords the technical advantage, in particular, that an even better dissipation of thermal energy may be brought about by this means.

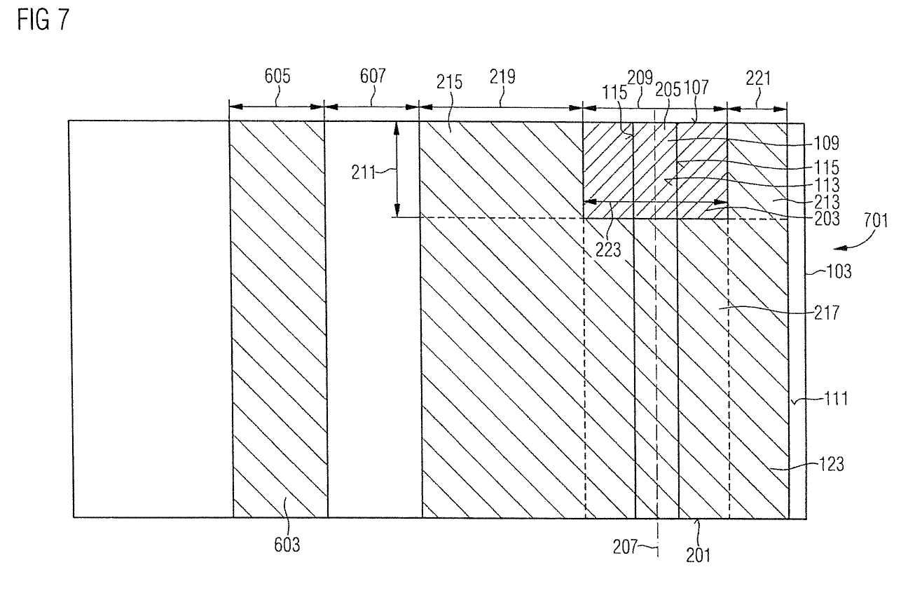

FIG. 7 shows a fifth semiconductor laser 701 in a plan view of the top side 111 of the semiconductor layer sequence 103.

The current flow layer 123 is substantially configured analogously to the current flow layer 123 in accordance with the semiconductor laser 101 from FIG. 2, although here a width of the semiconductor layer sequence 123 is reduced.

Analogously to FIG. 6, here as well a further current flow layer 603 is provided in a manner spaced apart from the current flow layer 123. The explanations given in association with FIG. 6 are analogously applicable.

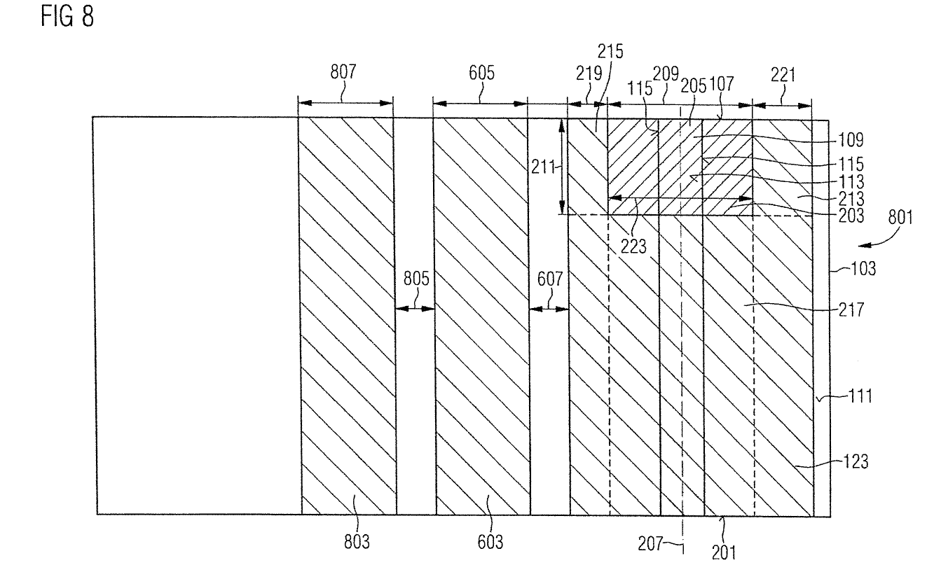

FIG. 8 shows a sixth semiconductor laser 801 in a plan view of the top side 111 of the semiconductor layer sequence 103.

The semiconductor laser 801 is substantially configured analogously to the semiconductor laser 701 from FIG. 1. As a difference, here a second further current flow layer 803 is also provided, which is applied in a manner spaced apart from the further current flow layer 603 on the top side 111 of the semiconductor layer sequence 103. This distance is identified by a double-headed arrow with the reference sign 805. The distance 805 corresponds, for example, to the distance 607. Correspondingly, by way of example, a width 807 of the further current flow layer 803 corresponds to the width of the further current flow layer 603.

In examples not shown, a plurality of further current flow layers are provided, which, analogously to the further current flow layers 803, 603, are applied in a strip-shaped fashion on the top side 111 of the semiconductor layer sequence 103.

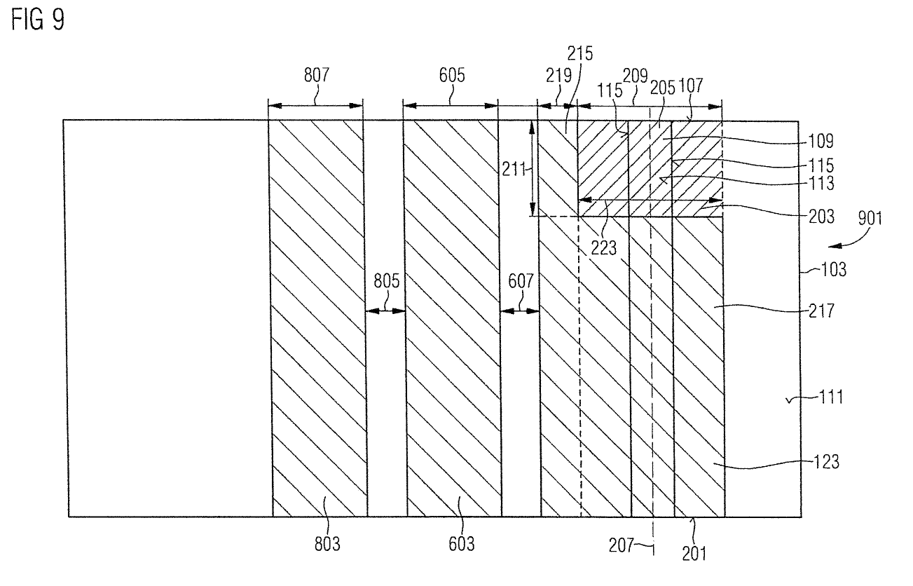

FIG. 9 shows a seventh semiconductor laser 901 in a plan view of the top side 111 of the semiconductor layer sequence 103.

The semiconductor laser 901 is substantially configured analogously to the semiconductor laser 601 from FIG. 6. As a difference, a further current flow layer 803 is provided, analogously to the semiconductor laser 801 from FIG. 8. The explanations given in association with FIG. 8 thus analogously also apply to the semiconductor laser 901 in FIG. 9.

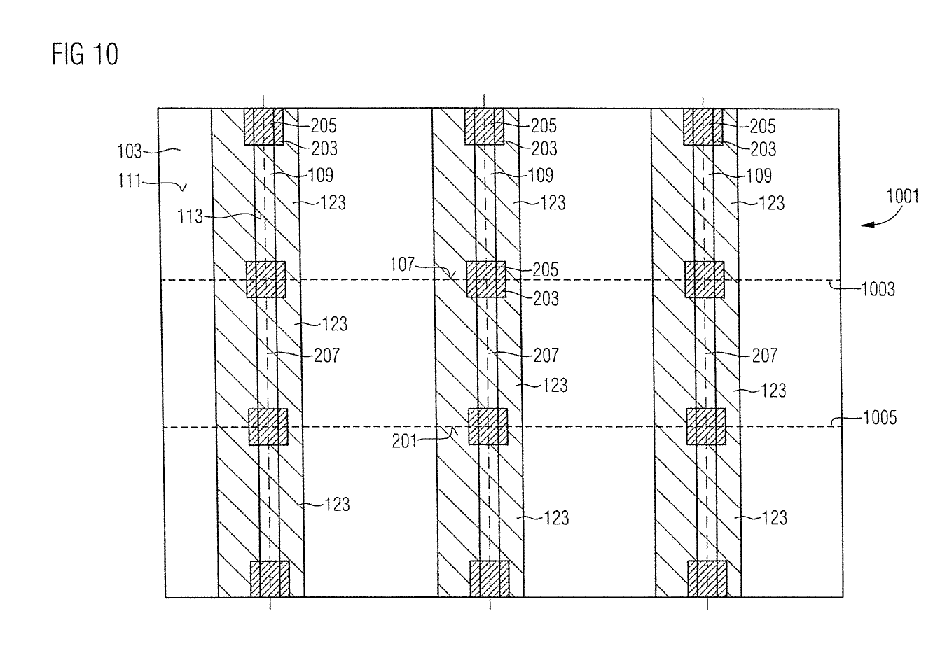

FIG. 10 shows a wafer 1001.

A semiconductor layer sequence 103 is applied, for example, grown on the wafer 1001, wherein three ridge waveguides 109 are configured. Furthermore, two breaking lines 1003, 1005 are depicted in a dashed manner along which the wafer 1001 and hence the semiconductor layer sequence 103 is intended to be broken. The breaking is carried out along a breaking trench, for example, which is not depicted here for the sake of clarity. In other words, the semiconductor layer sequence 103 and the wafer 1001 comprise, at suitable locations, breaking trenches along which the wafer 1001 with the semiconductor layer sequence 103 is broken, with the result that the facets 107, 201 may then form along the two breaking lines 1003, 1005.

Prior to braking, the current flow layer 123 is applied on the top side 111 and on the top side 113. In this case, a section is configured analogously to the section 203 as described and depicted in association with FIGS. 1 to 9. In other words, no current flow layer 123 is applied in the region of the breaking lines 1003, 1005. Consequently, there are regions, the sections 203 free of the current flow layer 123 and adjoin the future facets and comprise a subsection of the top side 113 of the ridge waveguide 109.

By leaving free these regions with the current flow layer 123, it is possible to achieve improved breaking qualities, which has already been explained in greater detail above.

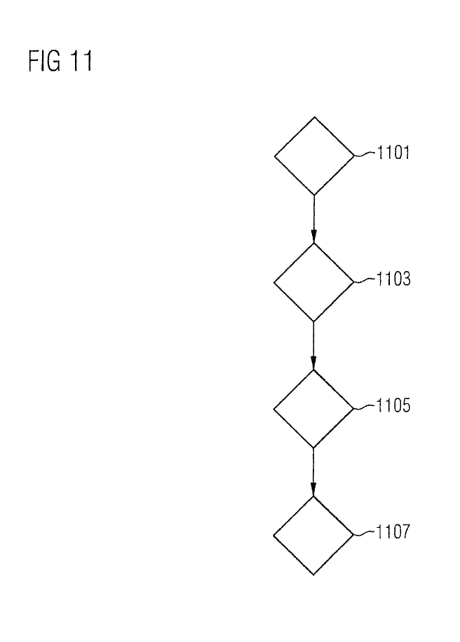

FIG. 11 shows a flow diagram of a method of producing a semiconductor laser.

The method comprises the following steps:
providing 1101 a semiconductor layer sequence comprising an active zone, wherein the semiconductor layer sequence comprises a ridge waveguide configured from the semiconductor layer sequence as an elevation of a top side of the semiconductor layer sequence, the elevation lying above the active zone, and the longitudinal axis of which is oriented along the active zone, wherein a contact metalization is applied on a top side of the ridge waveguide facing away from the active zone,
defining 1103 two breaking lines extending transversely with respect to the longitudinal axis of the ridge waveguide and parallel to the top side of the semiconductor layer sequence,
applying 1105 a current flow layer on the semiconductor layer sequence such that, after the applying, the current flow layer is in direct contact with the contact metalization,
wherein the top side of the semiconductor layer sequence comprises a section adjoining one of the two breaking lines over the width of the section relative to a longitudinal axis of the ridge waveguide, wherein the section comprises at least one subsection of the top side of the ridge waveguide, the subsection extends in a manner adjoining the one of the two breaking lines over a width of the ridge waveguide relative to the longitudinal axis of the ridge waveguide, and the section is free of the current flow layer, and
breaking 1107 the semiconductor layer sequence along the two breaking lines such that two opposite facets, which define a resonator, are formed along the two breaking lines, wherein the active zone is configured between the two facets.

To summarize, we provide an efficient concept on the basis of which a positive effect on the stress and on a breaking behavior may be achieved. In this case, the current flow layer may be structured such that a region adjoining the facets or one of the facets remains free of the current flow layer, wherein the region concomitantly comprises at least one subsection of the top side of the ridge waveguide.

Although our semiconductors lasers, methods and wafers have been more specifically illustrated and described in detail by preferred examples, nevertheless this disclosure is not restricted by the examples disclosed and other variations in may be derived therefrom by those skilled in the art, without departing from the scope of protection of the appended claims.

This application claims priority of DE 10 2015 119 146.6, the subject matter of which is incorporated herein by reference.

1-15. (canceled)

16. A semiconductor laser comprising:
a semiconductor layer sequence comprising two opposite facets defining a resonator, and an active zone configured between the two facets,
a ridge waveguide configured from the semiconductor layer sequence as an elevation of a top side of the semiconductor layer sequence, said elevation lying above the active zone, and the longitudinal axis of which is oriented along the active zone,
a contact metalization applied on a top side of the ridge waveguide facing away from the active zone, and
a current flow layer in direct contact with the contact metalization,
wherein the top side of the semiconductor layer sequence comprises a section adjoining one of the two facets over the width of said section relative to a longitudinal axis of the ridge waveguide, the section comprises a subsection of the top side of the ridge waveguide, the subsection extends in a manner adjoining said one of the two facets over a width of the ridge waveguide relative to the longitudinal axis of the ridge waveguide,
the section is partly delimited by a plurality of current flow layer sections of the current flow layer, and
the section is free of the current flow layer.

17. The semiconductor laser according to claim 16, wherein the width of the section relative to the longitudinal axis of the ridge waveguide is 30 μm to 80 μm.

18. The semiconductor laser according to claim 16, wherein a length of the section relative to the longitudinal axis of the ridge waveguide is 5 μm to 50 μm.

19. The semiconductor laser according to claim 16, wherein relative to the longitudinal axis of the ridge waveguide a respective width of said one or said plurality of current flow layer sections is 30 μm to 100 μm.

20. The semiconductor laser according to claim 16, wherein at least one further current flow layer spaced apart from the current flow layer is applied on the top side of the semiconductor layer sequence.

21. The semiconductor laser according to claim 20, wherein a respective width of the at least one further current flow layer relative to the longitudinal axis of the ridge waveguide is 10 μm to 40 μm.

22. The semiconductor laser according to claim 16, wherein the section comprises a quadrilateral shape, one side of the quadrilateral is delimited by the facet, and the other three sides of the quadrilateral shape are delimited by the current flow layer sections of the current flow layer.

23. A method of producing a semiconductor laser comprising:
providing a semiconductor layer sequence comprising an active zone, wherein the semiconductor layer sequence comprises a ridge waveguide configured from the semiconductor layer sequence as an elevation of a top side of the semiconductor layer sequence, said elevation lying above the active zone, and the longitudinal axis of which is oriented along the active zone, wherein a contact metalization is applied on a top side of the ridge waveguide facing away from the active zone,
defining two breaking lines extending transversely with respect to the longitudinal axis of the ridge waveguide and parallel to the top side of the semiconductor layer sequence,
applying a current flow layer on the semiconductor layer sequence such that, after the applying, the current flow layer is in direct contact with the contact metalization,
wherein the top side of the semiconductor layer sequence comprises a section adjoining one of the two breaking lines over the width of said section relative to a longitudinal axis of the ridge waveguide, the section comprises at least one subsection of the top side of the ridge waveguide, the subsection extends in a manner adjoining said one of the two breaking lines over a width of the ridge waveguide relative to the longitudinal axis of the ridge waveguide, the section is partly delimited by a plurality of current flow layer sections of the current flow layer, and the section is free of the current flow layer, and
breaking the semiconductor layer sequence along the two breaking lines such that two opposite facets defining a resonator are formed along the two breaking lines, wherein the active zone is configured between the two facets.

24. The method according to claim 23, wherein the width of the section relative to the longitudinal axis of the ridge waveguide is 30 μm to 80 μm.

25. The method according to claim 23, wherein a length of the section relative to the longitudinal axis of the ridge waveguide is 5 μm to 50 μm.

26. The method according to claim 23, wherein relative to the longitudinal axis of the ridge waveguide a respective width of said one or said plurality of current flow layer sections is 30 μm to 100 μm.

27. The method according to claim 23, wherein at least one further current flow layer spaced apart from the current flow layer is applied on the top side of the semiconductor layer sequence.

28. The method according to claim 26, wherein a respective width of the at least one further current flow layer relative to the longitudinal axis of the ridge waveguide is 10 μm to 40 μm.

29. The method according to claim 23, wherein the section comprises a quadrilateral shape, one side of the quadrilateral is delimited by the facet, and the other three sides of the quadrilateral shape are delimited by the current flow layer sections of the current flow layer.

30. A wafer comprising:
a semiconductor layer sequence comprising an active zone, wherein the semiconductor layer sequence comprises a ridge waveguide configured from the semiconductor layer sequence as an elevation of a top side of the semiconductor layer sequence, said elevation lying above the active zone, and the longitudinal axis of which is oriented along the active zone, and a contact metalization is applied on a top side of the ridge waveguide facing away from the active zone,
two breaking trenches defining two breaking lines extending transversely with respect to the longitudinal axis of the ridge waveguide and parallel to the top side of the semiconductor layer sequence,
a current flow layer in direct contact with the contact metalization,
wherein the top side of the semiconductor layer sequence comprises a section adjoining one of the two breaking linesover the width of said section relative to a longitudinal axis of the ridge waveguide, the section comprises at least one subsection of the top side of the ridge waveguide, the subsection extends in a manner adjoining said one of the two breaking lines over a width of the ridge waveguide relative to the longitudinal axis of the ridge waveguide, the section is partly delimited by a plurality of current flow layer sections of the current flow layer, and the section is free of the current flow layer.
